(19) United States
(12) Patent Application Publication
(10) Pub. No.: US 2010/0027213 A1
(43) Pub. Date: Feb. 4, 2010

(54) SERVER

(75) Inventors: Jian-Feng Wu, Shanghai City (CN); Shou-Jen Yang, Taipei City (TW)

Correspondence Address: J C PATENTS, 4 VENTURE, SUITE 250, IRVINE, CA, 92618, US

(73) Assignee: Inventec Corporation, Taipei City (TW)

(21) Appl. No.: 12/330,820

(22) Filed: Dec. 9, 2008

(30) Foreign Application Priority Data
Jul. 31, 2008 (CN) 200810129607.4

(51) Int. Cl. H05K 5/02; H05K 7/20

(52) U.S. Cl. 361/679.39; 361/679.48; 361/679.58

(57) ABSTRACT

A server includes a chassis, a hard disk array, a motherboard module array, a power supply and a fan module. The hard disk array is disposed in the accommodating space and exposed outside the front end of the chassis. The motherboard module array is disposed in the accommodating space and includes a set of dividing plates and several motherboard modules. The dividing plates are disposed in parallel to the two side walls in the chassis and have at least one set of supporting rails extending inwards. Each of the motherboard modules has a motherboard having components and an extractable tray supporting the motherboard. The extractable tray is disposed on the supporting rails. The power supply is disposed in the accommodating space and exposed outside the rear end of the chassis. The fan module is disposed in the accommodating space and between the motherboard module array and the hard disk array.

### CROSS-REFERENCE TO RELATED APPLICATION

This application claims the priority benefit of P.R.C. patent application serial no. 200810129607.4, filed on Jul. 31, 2008. The entirety of the above-mentioned patent application is hereby incorporated by reference herein and made a part of specification.

### BACKGROUND OF THE INVENTION

1. Field of the Invention

The present invention is related to a server, and particularly to a server easy to repair and maintain.

2. Description of Related Art

A server is the core which serves all the computers in a network system and has the functions of providing network users discs, printing service, and so forth. Also, the server allows the users to share the resources in the network. The basic frame of the server is approximately the same as that of an ordinary personal computer and comprises a CPU, a memory, and I/O equipment, which are connected by a bus inside. Through north bridge chips, the CPU and the memory are connected, and through south bridge chips, the CPU and the I/O equipment are connected. Based on the structure of a chassis, the development of the server may be roughly divided into three phases: developing from the early tower chassis to the rack mountable chassis which focuses on compact property, and then to the blade server which focuses on high-frequency calculation.

The rack mountable server is given as an example here. The rack mountable server is a server which has appearance of standard design and used together with the chassis. In other words, the rack mountable server is a tower server having superior design, and its purpose is to reduce the space occupied in the server as much as possible. A great deal of network equipment adopts the rack mountable structure, which is mostly flat type, like drawers. The aforesaid network equipments are, for example, exchangers, routers, and hardware firewalls. The rack mountable server is 19 inches wide, and the height thereof is measured by the unit, U (1U=1.75 inches=44.45 millimeters). Generally speaking, the server is classified into 1U, 2U, 3U, 4U, 5U, and 7U types.

The size of the chassis is also regulated by industrial standards, generally from 22U to 42U. Detachable sliding trays may be disposed in the chassis based on the height (U) of the chassis. The user may flexibly adjust the height, according to the level of the server, for storing network equipment, such as servers, hubs, and disc array cabinets. After the server is placed, all the I/O wires thereof may be led out from the rear of the chassis and organized in the wire trenches of the chassis (all the interfaces of the rack mountable server are also located at the rear). Number labels are commonly used to facilitate management.

Generally speaking, the rack mountable server is designed to have one single motherboard inside, and the single motherboard is usually fixed on the chassis. When the motherboard fails, it is inconvenient for the user to disassemble and replace the motherboard, which causes trouble in maintenance. In addition, when parts of the components on the motherboard fail, it is still necessary to replace the whole motherboard, which puts the whole rack mountable server in shutdown status. Consequently, the rack mountable server cannot remain in normal operation for a long period of time.

### SUMMARY OF THE INVENTION

The present invention provides a server including a plurality of motherboard modules, and each of the plurality of motherboard modules is capable of being maintained and repaired individually. Furthermore, the space in the same chassis contains a plurality of motherboard modules that share a power supply and a fan module so as to increase utilization of the chassis space.

The present invention provides a server including a chassis, a hard disk array, a motherboard module array, a power supply and a fan module. The chassis is used to define a containing space and has a bottom board, two side walls, a front end and a rear end. The hard disk array is disposed in the accommodating space and exposed outside the front end of the chassis. The motherboard module array is disposed in the accommodating space and includes at least one set of dividing plates and a plurality of motherboard modules. The dividing plates are disposed in parallel to the two side walls in the chassis and have at least one set of supporting rails extending inwards. Each of the motherboard modules includes a motherboard having a plurality of components and an extractable tray supporting the motherboard. The extractable tray is disposed on the supporting rails and suitable for being pulled out from the rear end of the chassis. The power supply is disposed in the accommodating space and exposed outside the rear end of the chassis. The fan module is also disposed in the accommodating space and located between the motherboard module array and the hard disk array.

According to an embodiment of the present invention, the dividing plates include a first dividing plate and a second dividing plate both assembled to the chassis. The second dividing plate is substantially parallel to the first dividing plate, and a distance is maintained between the first dividing plate and the second dividing plate.

According to an embodiment of the present invention, the supporting rails include a first supporting rail and a second supporting rail. The first supporting rail extends from the first dividing plate towards the second dividing plate, and the second supporting rail extends from the second dividing plate towards the first dividing plate.

According to an embodiment of the present invention, the first supporting rail and the second supporting rail are arranged on a same plane.

According to an embodiment of the present invention, the chassis includes a lower housing and an upper housing assembled to the lower housing.

According to an embodiment of the present invention, the components include at least one heat sink, at least one central processing unit (CPU), at least one control chip, at least one memory and at least one data I/O connection terminal.

According to an embodiment of the present invention, the extractable tray includes a supporting bottom plate and a rear end panel. The supporting bottom plate is suitable for supporting the motherboard. The rear end panel is connected to the supporting bottom plate and extends upwards from an edge of the supporting bottom plate.

According to an embodiment of the present invention, the rear end panel has a plurality of holes.

According to an embodiment of the present invention, the rear end panel is disposed at the rear end of the chassis.

According to an embodiment of the present invention, the supporting bottom plate is parallel to the bottom plate of the chassis.

According to an embodiment of the present invention, each of the motherboard modules further includes an elastic latch connected to the extractable tray, and each of the dividing plates further includes a latching hole. The elastic latch is suitable for clasping the latching hole to maintain the motherboard within the chassis.

According to an embodiment of the present invention, the fan module includes a plurality of fans arranged side by side.

According to an embodiment of the present invention, the motherboard module array further includes a plurality of motherboard modules and a plurality of sets of dividing plates arranged as adjacent to one another in sequence. The motherboard modules are disposed on the sets of supporting rails of the sets of dividing plates, and each of the motherboard modules among the dividing plates of the same set is stacked sequentially on one another.

The server of the present invention includes a plurality of motherboard modules capable of operating jointly, and each of the motherboard modules is disposed on each of the extractable trays respectively. Therefore, a portion of the extractable tray can be pulled out from the chassis in order for a portion of the motherboard module to be maintained and repaired without affecting the operation of the server.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a server according to an embodiment of the present invention.

FIGS. 2 and 3 are perspective views of a portion of the structure of the server in FIG. 1.

### DESCRIPTION OF EMBODIMENTS

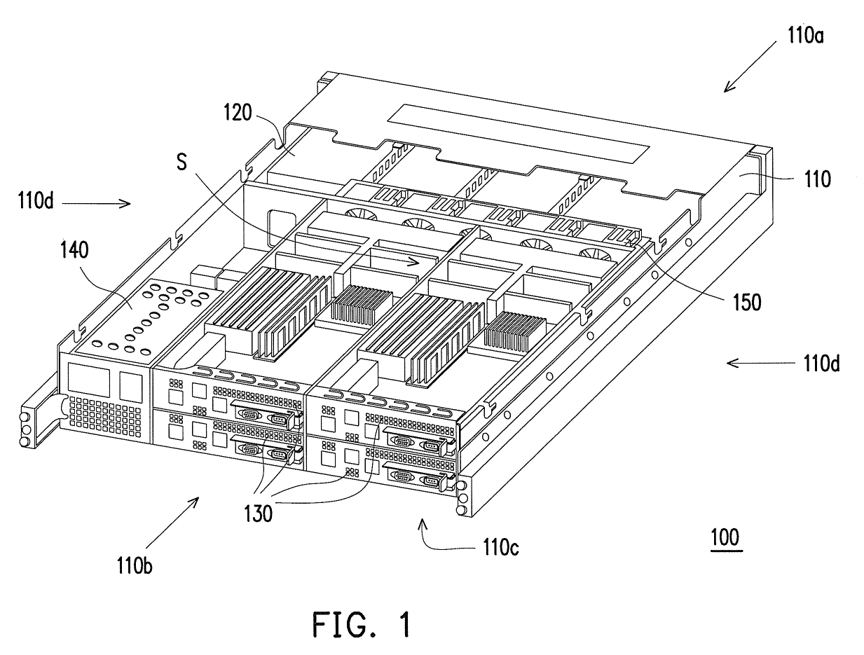

FIG. 1 is a perspective view of a server according to an embodiment of the present invention. Referring to FIG. 1, a server 100 of the present embodiment includes a chassis 110, a hard disk array 120, a motherboard module array 130, a power supply 140 and a fan module 150. The chassis 110 is used to define an accommodating space S and has a front end 110a, a rear end 110b, a bottom plate 110c and two side walls 110d. The hard disk array 120 is disposed in the accommodating space S and exposed outside the front end 110a of the chassis 110. The power supply 140 is disposed in the accommodating space S and exposed outside the rear end 110b of the chassis 110. The fan module 150 is also disposed in the accommodating space S and located between the motherboard module array 130 and the hard disk array 120.

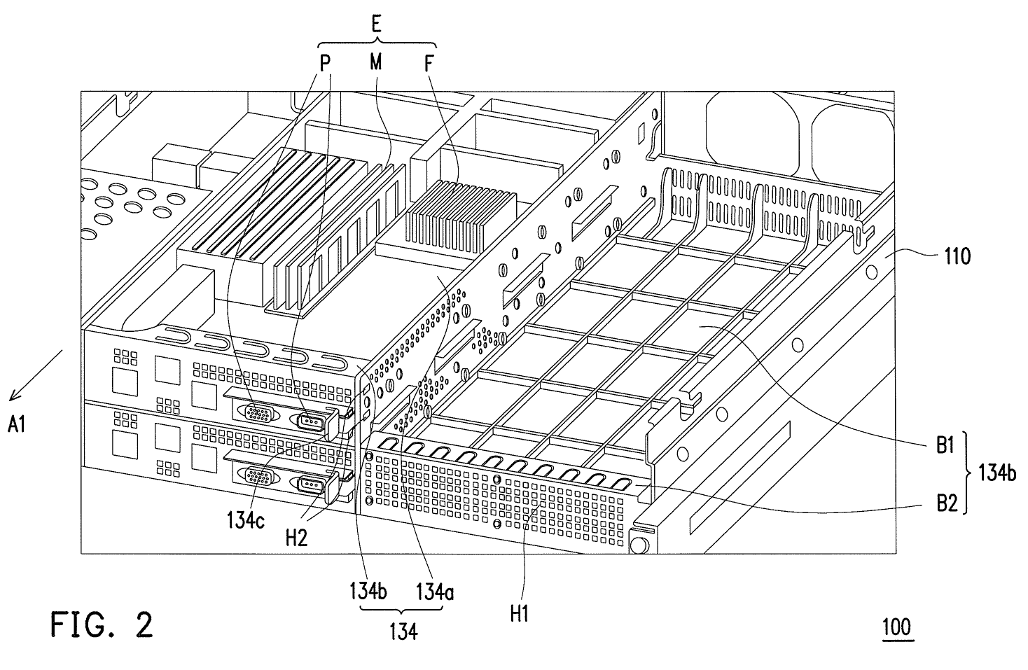

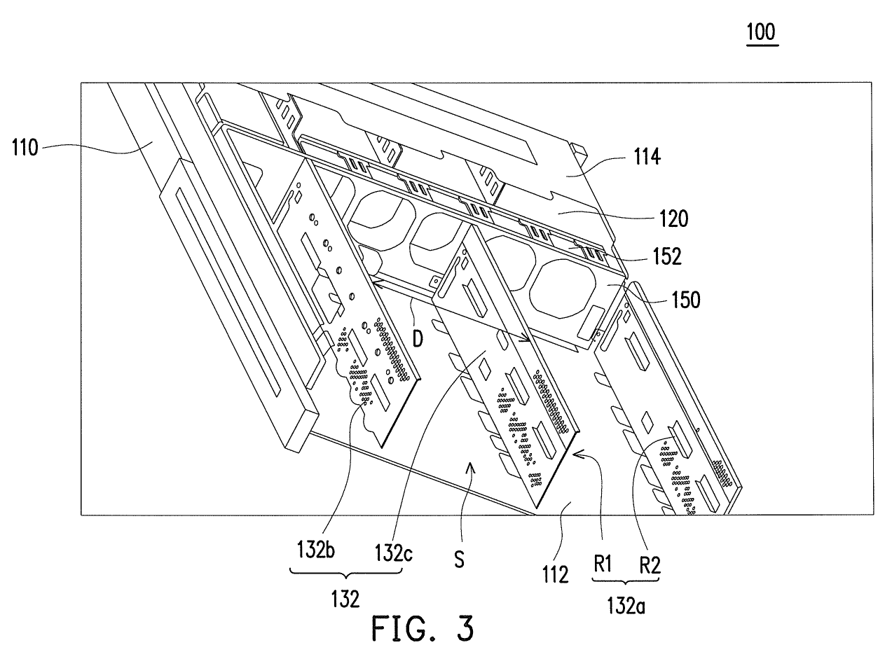

FIGS. 2 and 3 are perspective views of a portion of the structure of the server in FIG. 1. Referring to FIGS. 2 and 3, the motherboard module array 130 is disposed in the accommodating space S and includes at least one set of dividing plates 132 (as illustrated for example by the two sets of dividing plates 132 in FIG. 2) and a plurality of motherboard modules 134. The dividing plates 132 are disposed in parallel to the two side walls 110d in the chassis 110 and have at least one set of supporting rails 132a extending inwards. Each of the motherboard modules 134 has a motherboard 134a having a plurality of components E and an extractable tray 134b supporting the motherboard 134a. The extractable tray 134b is disposed on the supporting rails 132a and suitable for being pulled out from the rear end 110b of the chassis 110 towards a direction Al. Thus, each of the motherboard modules 134 can be maintained and repaired individually by pulling out each of the extractable trays 134b from the chassis 110 respectively.

The present embodiment is exemplified by a set of dividing plates 132 for illustration, but the present invention does not limit the motherboard module array 130 as having only one set of dividing plates 132. Specifically, the motherboard module array 130 may further include other sets of dividing plates, and each set of dividing plates have the same structure so as to facilitate mass production. In addition, each set of dividing plates can be arranged tightly in sequence to increase the structure strength and allow more flexibility in utilization of the space inside the chassis.

Referring to FIG. 3, according to the present embodiment, the dividing plates 132 include a first dividing plate 132b and a second dividing plate 132c assembled to the chassis 110. The second dividing plate 132c is substantially parallel to the first dividing plate 132b, and a distance D is maintained between the first dividing plate 132b and the second dividing plate 132c. The supporting rails 132a include a first supporting rail R1 and a second supporting rail R2. The first supporting rail R1 extends from the first dividing plate 132b towards the second dividing plate 132c, and the second supporting rail R2 extends from the second dividing plate 132c towards the first dividing plate 132b. The first supporting rail R1 and the second supporting rail R2 are arranged on the same plane. Furthermore, the fan module 150 includes a plurality of fans 152 arranged side by side. The chassis 110 includes a lower housing 112 and an upper housing 114 assembled to the lower housing 112.

The present embodiment is exemplified by the first supporting rail R1 and the second supporting rail R2 for illustration. However, the present invention does not limit the supporting rails 132a as having only the first supporting rail R1 and the second supporting rail R2. In detail, the supporting rails 132a may further include other supporting rails, and the other supporting rails are located on another plane (different from the plane where the first supporting rail R1 and the second supporting rail R2 are located). In other words, the supporting rails 132a may include four, six or more sets of supporting rails. Thus, the first dividing plate 132b and the second dividing plate 132c can carry two or more motherboard modules 134.

Referring to FIGS. 1 and 2, according to the present embodiment, the components E include at least one heat sink F, at least one CPU (not shown), at least one control chip (not shown), at least one memory M and at least one data I/O connection terminal P. The extractable tray 134b includes a supporting bottom plate B1 and a rear end panel B2. The supporting bottom plate B1 is parallel to the bottom plate 110c of the chassis 110 and suitable for supporting the motherboard 134a. The rear end panel B2 is disposed at the rear end 110b of the chassis 110 and connected to the supporting bottom plate B1. The rear end panel B2 also extends upwards from an edge of the supporting bottom plate B1. The rear end panel B2 can be a single component or constituted by a plurality of sub-components. The data I/O connection terminals P are exposed by the rear end panel B2, and the rear end panel B2 has a plurality of holes H1. The holes H1 include holes for dissipation and holes for exposing the data I/O connection terminals P.

Referring to FIG. 2, according to the present embodiment, each of the motherboard modules 134 further includes an elastic latch 134c connected to the extractable tray 134b, and the dividing plates 132 further include a plurality of latching holes H2. The elastic latch 134c is suitable for clasping the latching holes H2 to maintain the motherboard module 134 within the chassis 110. Certainly, in the present invention, other mechanical designs may also be used to fix the extractable tray 134b. The present invention is not limited to use of the elastic latch 134c as shown in FIG. 2.

In summary, the server of the present invention includes a plurality of motherboard modules capable of operating jointly, and each of the motherboard modules is respectively disposed on each individual extractable tray. Therefore, when the motherboard module needs to be maintained or a portion of the motherboard module is out of order, maintenance staff can pull out a portion of the extractable tray from the chassis so as to maintain and repair the malfunctioning portion of the motherboard module without affecting the operation of the entire server. Furthermore, the space of the same chassis contains a plurality of motherboard modules that share a power supply and a fan module so as to increase utilization of the chassis space.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A server, comprising:
a chassis for defining an accommodating space, the chassis comprising a bottom plate, two side walls, a front end and a rear end;
a hard disk array disposed in the accommodating space and exposed outside the front end of the chassis; and
a motherboard module array disposed in the accommodating space and located at the rear end of the accommodating space, the motherboard module array comprising:
at least one set of dividing plates disposed in the chassis and in parallel to the two side walls and having at least one set of supporting rails extending inwards; and
a plurality of motherboard modules, each of the plurality of motherboard modules comprising:
a motherboard having a plurality of components;
an extractable tray supporting the motherboard, wherein the extractable tray is disposed on the set of supporting rails and suitable for being pulled out from the rear end of the chassis; and
a power supply disposed adjacent to the motherboard module array in the accommodating space and exposed outside the rear end of the chassis; and
a fan module disposed in the accommodating space and located between the motherboard module array and the hard disk array.

2. The server as claimed in claim 1, wherein the set of dividing plates comprise:
a first dividing plate assembled to the chassis; and
a second dividing plate substantially parallel to the first dividing plate and assembled to the chassis, wherein a distance is maintained between the first dividing plate and the second dividing plate.

3. The server as claimed in claim 2, wherein the set of supporting rails comprise:
a first supporting rail extending from the first dividing plate towards the second dividing plate; and
a second supporting rail extending from the second dividing plate towards the first dividing plate.

4. The server as claimed in claim 3, wherein the first supporting rail and the second supporting rail are arranged on a same plane.

5. The server as claimed in claim 1, wherein the chassis comprises:
a lower housing; and
an upper housing assembled to the lower housing.

6. The server as claimed in claim 1, wherein the plurality of components comprise at least one heat sink, at least one central processing unit, at least one control chip, at least one memory and at least one data input/output (I/O) connection terminal.

7. The server as claimed in claim 1, wherein the extractable tray comprises:
a supporting bottom plate for supporting the motherboard; and
a rear end panel connected to the supporting bottom plate and extending upwards from an edge of the supporting bottom plate.

8. The server as claimed in claim 7, wherein the rear end panel has a plurality of holes.

9. The server as claimed in claim 7, wherein the rear end panel is disposed at the rear end of the chassis.

10. The server as claimed in claim 7, wherein the supporting bottom plate is parallel to the bottom plate of the chassis.

11. The motherboard module array as claimed in claim 1, wherein each of the plurality of motherboard modules further comprises an elastic latch connected to the extractable tray, and the set of dividing plates further comprise a latching hole, the elastic latch being suitable for clasping the latching hole so that the motherboard module is maintained within the chassis.

12. The server as claimed in claim 1, wherein the fan module comprises a plurality of fans arranged side by side.

13. The server as claimed in claim 1, wherein the motherboard module array further comprises a plurality of motherboard modules and a plurality of sets of dividing plates arranged adjacent to one another in sequence, and the motherboard modules are disposed on the sets of supporting rails of the sets of dividing plates, each of the motherboard modules between the dividing plates of the same set being sequentially stacked on one another.
